(19) United States
(12) Patent Application Publication
(10) Pub. No.: US 2006/0234454 A1
(43) Pub. Date: Oct. 19, 2006

(54) Method of fabricating nonvolatile semiconductor memory devices with uniform sidewall gate length

(76) Inventors: Kan Yasui, Kodaira (JP); Shinichiro Kimura, Kunitachii (JP); Digh Hisamoto, Kokubunji (JP); Tetsuya Ishimaru, Kokubunji (JP)

Correspondence Address: MATTINGLY, STANGER, MALUR & BRUNDIDGE, P.C., 1800 DIAGONAL ROAD, SUITE 370, ALEXANDRIA, VA, 22314, US

(21) Appl. No.: 11/404,899

(22) Filed: Apr. 17, 2006

(30) Foreign Application Priority Data
Apr. 18, 2005 (JP) JP2005-119282

(51) Int. Cl. H01L 21/336

(52) U.S. Cl. 438/267

(57) ABSTRACT

After forming a first dielectric film on the main surface of a semiconductor substrate, a first conductive film is formed on the first dielectric film, and then, the surface of the first conductive film is planarized by a CMP method. Subsequently, the first conductive film and the first dielectric film are etched, thereby forming a select gate having a first gate electrode and a first gate dielectric film. Subsequently, after forming a second dielectric film on the sidewall of the first gate electrode and the main surface, a second conductive film is formed on the second dielectric film, and the second conductive film is etched, thereby forming a memory gate having a second gate electrode and a second gate dielectric film.

### CROSS-REFERENCE TO RELATED APPLICATION

The present application claims priority from Japanese Patent Application No. JP 2005-119282 filed on Apr. 18, 2005, the content of which is hereby incorporated by reference into this application.

### TECHNICAL FIELD OF THE INVENTION

The present invention relates to a method of fabricating a nonvolatile semiconductor memory device. More particularly, it relates to a technology effectively applied to the fabrication of a semiconductor nonvolatile memory cell.

### BACKGROUND OF THE INVENTION

A nonvolatile semiconductor memory device can be realized as a high-performance semiconductor device by embedding a semiconductor nonvolatile memory cell (hereinafter referred to as “memory cell”) on the same semiconductor substrate together with a logic device such as a MOS transistor and others. This nonvolatile semiconductor memory device is widely used as an embedded microcomputer in industrial machines, home appliances, on-vehicle equipment, and the like. In general, a program required for the microcomputer is stored in an embedded memory cell, and this program is read and used from time to time. As a cell structure of the memory cell suitable for embedding with a logic device, a split gate type memory cell comprising a select MOS (Metal Oxide Semiconductor) transistor and a memory MOS transistor is known.

In the nonvolatile semiconductor memory device, since this split gate type memory cell can adopt a SSI (Source Side Injection) having good injection efficiency, it is possible to increase the programming speed and reduce an area for a high voltage power supply unit. Also, since the select MOS transistor of the memory cell and transistors connected thereto can be formed by low voltage transistors having a small area, it is possible to reduce the area of a peripheral circuit. Accordingly, the split gate memory cell is suitable for embedded devices.

The method of charge retention of a memory MOS transistor includes a floating gate method and a MONOS (Metal Oxide Nitride Oxide Semiconductor) method. In Japanese Patent Application Laid-Open Publication No. 5-121700 (Patent Document 2) and Proceedings of IEEE 1994 Symposium on VLSI Technology, Pages 71 and 72 (Non-Patent Document 1), the floating gate method is described, in which charge is stored in conductive polysilicon (polycrystalline silicon) which is electrically isolated. Further, in Japanese Patent Application Laid-Open Publication No. 5-48113 (Patent Document 1) and Proceedings of IEEE 1997 Symposium on VLSI Technology, Pages 63 and 64 (Non-Patent Document 2), the MONOS method is described, in which charge is stored in a dielectric film having a charge storing property such as a silicon nitride film.

Further, it is known that polysilicon is applied as a gate electrode material of the MOS transistor because of easiness of formation thereof and easiness of control of dopant doping. In U.S. Pat. No. 5,911,111 (Patent Document 4), when a patterning of the gate electrode of the MOS transistor is to be performed through a photolithography process, polysilicon is polished in order to remove the influence of a surface roughness due to the crystal grains of polysilicon to be a gate electrode material.

### SUMMARY OF THE INVENTION

The above-described floating gate method is widely used in a flash memory for storing a program for a mobile phone, a large-capacity flash memory for storing data, and others, and it is known to have good charge retention characteristic. However, along with the device scaling, it becomes difficult to keep a capacitance coupling ratio necessary for potential control of the floating gate, and the structure becomes complicated. Further, in order to suppress the leakage of retained charge, the thickness of a silicon oxide film surrounding the floating gate is required to be about 8 nm or more, and thus, the scaling for the purpose of higher performance and integration approaches its limit. Further, since a charge is stored in the conductive material of the floating gate, even if only one defect to be a leakage path exists in the silicon oxide film surrounding the floating gate, a charge retention time is extremely shortened.

In this point, since the MONOS keeps a charge in discrete trap in an insulating material, all the retained charges are not lost even if there are some leakage paths, and it is resistant to oxide film defects. Consequently, along with the device scaling, the MONOS method is considered advantageous because the thin oxide film even below 8 nm is applicable which is suitable for scaling, reliability prediction is facilitated since retention time is not extremely reduced due to the defect which occurs with low probability, and a memory cell structure is simple and is easily embedded with a logic circuit.

In the memory cell which adopts this MONOS method, as a split gate structure particularly suitable for scaling, there is the structure in which the memory MOS transistor (hereinafter referred to as “memory transistor”) is formed as a sidewall on the sidewall of the select MOS transistor (hereinafter referred to as “select transistor”) by utilizing a self align structure (Patent Document 1 and Non-Patent Document 2). In the case of this sidewall structure, since alignment margin for photolithography is not required and the gate length of the transistor formed by self align method can be reduced below the minimum resolution size of the photolithography, a smaller memory cell can be realized in comparison with the conventional structure which forms the adjacent two types of transistors by photomasks.

Further, from among the split gate type memory cells utilizing the self align structure, the memory cell in which a self align gate is formed to have the MONOS structure (Japanese Patent Application Laid-Open Publication No. 2004-186452 (Patent Document 3) and Non-Patent Document 2) is suitable for embedding with a high-speed logic circuit unit.

A split gate type MONOS (Metal Oxide Nitride Oxide Semiconductor) memory cell having a select transistor and a memory transistor and the fabricating method thereof studied by the inventors of the present invention will be described below.

FIG. 17 is a cross-sectional view schematically showing a memory cell 50 studied by the inventors of the present invention. For example, on a semiconductor substrate 51 made of silicon, an ONO (Oxide Nitride Oxide) film composed of a bottom oxide film 13 made of a silicon oxide (SiO₂) film, a trap dielectric film 14 made of a silicon nitride (SiN) film, and a top oxide film 15 made of a silicon oxide (SiO₂) film and a memory gate electrode 11 of a sidewall structure are formed on the sidewall of a select gate electrode 12. The gate electrode material (conductive film) of this select gate electrode 12 is made of polysilicon, and the gate electrode material (conductive film) of the memory gate electrode 11 is made of amorphous silicon. Note that silicide layers 16 are formed on each of a doped region 7, a doped region 5, the select gate electrode 12, and the memory gate electrode 11, and a select gate dielectric film 6 is formed between the select gate electrode 12 and the semiconductor substrate 51.

Due to the structural restriction of this memory cell 50, the select gate electrode 12 is formed prior to the memory gate electrode 11. Therefore, a gate dielectric film of the logic circuit can be formed simultaneously with the select gate dielectric film 6 of the select gate, while keeping an interface quality of the semiconductor substrate in a good state. Since a transistor having a thin film gate for high-speed operation which is sensitive to interface quality can be formed first, the performance of the logic circuit and select gate to be embedded is improved. The stored information can be read out by only the operation of the high-performance select gate transistor, and transistors connected to this transistor can be all configured by low-voltage thin-film transistors. Therefore, the speed-up of the reading and the reduction of the circuit area can be achieved.

FIG. 18 is an explanatory drawing of an array structure using the split gate type MONOS memory cell. In each memory cell, a memory gate 11a and an adjacent memory gate 11a share a doped region (hereinafter referred to as “source”), and source lines 1 (SL1 and SL2 of FIG. 18) formed from the source are provided. The source lines 1 extend in parallel with two types of word lines 2 (MG1 and MG2 of FIG. 18) and word lines 3 (CG1 to CG4 of FIG. 18). The word lines 2 are formed from the memory gate, and the word lines 3 are formed from the select gate. Bit lines 4 (BL1 and BL2 of FIG. 18) perpendicular to the source lines 1 and the word lines 2 and 3 are connected to the doped region (hereinafter referred to as “drain”) adjacent to the select gate 12a of the memory cell.

FIG. 19 is an explanatory drawing showing a plane layout of the array structure described above. Each unit memory cell is formed in a unit memory cell area 31, and is electrically isolated from an adjacent unit memory cell by an isolation area 33 (hatched are of FIG. 19). The drain or the source line 4 of the memory cell is electrically connected to other part through a contact 21.

FIG. 20 is an explanatory drawing showing voltage conditions at the time of operating the split gate type MONOS memory cell. Programming is performed in the following manner. That is, the select gate is in weak inversion by a SSI (Source Side Injection) method in a state where the memory gate and the source are applied with about 12 V and 5 V, respectively. Then, hot electrons are generated by a strong electric field generated between the select gate and the memory gate, and are injected into the memory gate. Erasing is performed by using a hot hole injection method by band to band tunneling (BTBT method). That is, by applying about −5 V and about 7 V which provide reverse biases to the memory gate and the source, respectively, hot hole by the band to band tunneling are generated by a strong electric field generated in an extension region, and then, the hot holes are injected into the memory gate. When the written information is to be read, 1.5 V is applied to both the memory gate and the select gate and 1V is applied to the drain, and then, the information to be read is determined based on the magnitude of the current flowing into the drain.

FIG. 21 to FIG. 28 are cross-sectional views schematically showing a memory cell and a transistor for a logic circuit in the fabricating process of a nonvolatile semiconductor memory device studied by the inventors of the present invention. Note that FIG. 21 to FIG. 28 also show the fabricating process in which the MOS transistor for a logic circuit (hereinafter referred to as “logic transistor”) to be embedded with the memory cell formed in a memory region 54 is formed in a logic region 55.

As shown in FIG. 21, for example, a dielectric film 53 and a conductive film 34 made of polysilicon are formed on the semiconductor substrate 51 made of p type single crystal silicon and having a p type well 52 formed therein. The well 52 is formed by introducing a p type dopant such as boron into the semiconductor substrate 51 by using, for example, the ion implantation method. Further, the dielectric film 53 is formed of silicon oxide having a thickness of about 4 nm formed by thermally oxidizing the semiconductor substrate 51 made of silicon. Further, for example, the conductive film 34 is formed to have a thickness of about 270 nm by a CVD (Chemical Vapor Deposition) method. Note that, although not shown in the drawing, as the preliminary step, an isolation area (isolation portion) is formed by using a known method.

Subsequently, as shown in FIG. 22, the gate electrodes of the select transistor and a logic transistor are formed by patterning the conductive film 34 by dry etching. More specifically, a gate process is simultaneously performed at this step so that the select transistor of the memory cell has the select gate electrode 12 and the select gate dielectric film 6 and the logic transistor has a logic gate electrode 17 and a logic dielectric film 56.

Subsequently, as shown in FIG. 23, an ONO film 18 of a three layer structure of the bottom oxide film 13, the trap dielectric film 14, and the top oxide film 15 is formed. The bottom oxide film 13 is formed of a silicon oxide film with a thickness of about 5 nm by the CVD method. Further, the trap oxide film 14 is formed of a silicon nitride film with a thickness of about 5 nm by the CVD method. Also, the top oxide film 15 is formed of a silicon oxide film with a thickness of about 5 nm by the CVD method.

Subsequently, as shown in FIG. 24, amorphous silicon doped with a dopant is deposited as the memory gate electrode material, and the amorphous silicon is etched-back by dry etching so that the conductive films 11 and 40 are left as sidewall electrodes on the sidewall of the select gate electrode 12 and conductive films 41 are left as sidewall electrodes on the sidewall of the logic gate electrode 17.

Subsequently, as shown in FIG. 25, from among the sidewall electrodes thus formed, unnecessary conductive films 40 and 41 are removed by etching, and moreover, the ONO films 18 below the conductive films 40 and 41 are similarly removed. Subsequently, a n type dopant (for example, phosphorous or arsenic) is ion-implanted into the well 52 at the sides of the sidewall of the select gate electrode 12, the memory gate electrode 11, and the logic gate electrode 17, thereby forming lightly doped regions 8. The lightly doped region 8 is an extension region for suppressing the short channel effect of each transistor.

Subsequently, as shown in FIG. 26, for example, after forming a silicon oxide film on the semiconductor substrate 51, the silicon oxide film is etched-back to form sidewalls 58. Then, a n type dopant (for example, phosphorous or arsenic) is ion-implanted into the substrate 52, thereby forming highly doped regions 9.

Subsequently, as shown in FIG. 27, silicidation process is performed in order to reduce the resistance of the select gate electrode 12 and the logic gate electrode 17, thereby forming a silicide layer 27.

Subsequently, as shown in FIG. 28, an interlayer dielectric film 42 made of a silicon oxide film is deposited on the semiconductor substrate 51. Then, the interlayer dielectric film 42 is planarized, and contact portions are formed therein. Thereafter, though the description thereof will be omitted, after standard metallization processes for about three to six layers, a nonvolatile semiconductor memory device is almost completed.

The method in which the gate electrodes of the select transistor and the logic transistor of the MONOS memory are simultaneously processed has been shown in FIG. 22. Alternatively, the method in which the select transistor only is processed first, and after the processes of FIG. 22 to FIG. 26, the gate electrode of the logic transistor is processed is also available. In this case, though one additional mask is required for patterning the gate electrode, adjustment of the characteristic of the logic transistor is easy because it is formed afterward.

The self align split gate MONOS memory cell whose fabricating process has been shown in FIG. 21 to FIG. 28 is characterized in that variation in the gate length of the memory transistor is small in comparison with the case where the self alignment is not utilized.

However, even the small variation is not yet sufficient for the customer requirement, and the further reduction in variation of the gate length of the memory transistor is desired. It will be described below in detail.

In the case of a split gate structure not utilizing the self alignment, the memory gate is shifted in position from the select gate by the alignment error of photolithography. This value is, for example, about 60 nm in KrF scanner used for the 130 to 180 nm node. In contrast to this, if the memory transistor is formed as a self align sidewall, an alignment error is zero, and thus, there exists only micro variation resulting from the processing. Therefore, the variation in the sidewall gate length, that is, the variation in the gate length of the memory transistor is in the range of about ±10 nm. Usually, the variation of about ±10 nm is within an allowable range. However, when priority is given to programming/erasing characteristics, the self align split gate type MONOS memory cell degrades the short channel characteristic of the memory transistor. When the short channel characteristic is degraded, characteristics such as threshold voltage and the like are easily fluctuated by slight variation in the gate length. Consequently, even when priority is given to programming/erasing characteristics, it is necessary to further suppress the variation in the gate length of the memory transistor so that characteristics such as the threshold voltage and the like are not fluctuated.

Here, the influence from the variation in the gate length of the memory transistor will be described by using the self align split gate type MONOS memory cell fabricated based on a design rule of 150 nm. FIG. 29 is an explanatory drawing of the relationship between the gate length of the memory transistor and I-V characteristic. FIG. 30 is an explanatory drawing of the relationship between the gate length of the memory transistor and a memory erasing speed.

The gate dielectric film of the memory transistor is composed of an ONO film having a three layer structure of SiO₂/SiN/SiO₂ for information storage with EOT (Equivalent Oxide Thickness) of 15 nm, which is thicker than the gate dielectric films of 4 nm of the select transistor and the logic transistor. Also, the gate length of the memory transistor is 65 nm and is microfabricated to such an extent of being much thinner than the gate lengths of 150 nm of the select transistor and the logic transistor. The short channel characteristic of the MOS transistor is degraded as the gate dielectric film becomes thicker and the gate length becomes shorter. Therefore, the short channel characteristic of the memory transistor is extremely inferior to that of the select transistor and the logic transistor. In particular, the characteristic is easily fluctuated by the change in the gate length.

As shown in FIG. 29, the I-V characteristic is largely changed when the gate length (Lmg) becomes shorter (55 nm and 45 nm) than the gate length of 65 nm. In this device, threshold voltage (Vth) is shifted by 1.5 V and the subthreshold slope is also changed due to the reduction in gate length of 10 nm. Further, in addition to the short channel characteristic, the memory gate length is also highly sensitive to the erasing characteristic.

As shown in FIG. 30, when the gate length (Lmg) becomes shorter by 10 nm from 65 nm to 55 nm, the erasing speed slows down by half a digit, and a not negligible difference arises in the array. At present, the variation in gate length of the memory transistor is about ±10 nm, and thus, the threshold voltage and the erasing speed vary widely in the array, and programming/erasing endurance and charge retention characteristic are degraded due to the increase in programming/erasing stress. Hence, in order to improve the short channel characteristic, it is effective to increase the gate length of the memory transistor, but it inevitably causes the degradation in the erasing speed as shown in FIG. 30. Also, when the thickness of the gate dielectric film of the memory transistor is reduced for the same purpose, the charge retention characteristic is degraded.

Hence, the inventors of the present invention have studied the process in which the variation in the gate length occurs in the memory transistor. FIG. 31 to FIG. 35 are explanatory drawings schematically showing a memory cell in the fabricating process of the nonvolatile semiconductor memory device studied by the inventors of the present invention, which show a process in which the variation in the gate length Lmg of the memory transistor occurs.

As shown in FIG. 31, after depositing the dielectric film 53 of the select transistor on the semiconductor substrate (not shown), a conductive film 34 made of, for example, polysilicon is deposited as the gate electrode material of the select transistor. Note that the crystal grain of polysilicon has a property that it grows in the columnar shape in the depositing direction of the film, and the surface after the deposition has a surface roughness of about 10 nm due to the growing variation of the crystal grains.

Subsequently, as shown in FIG. 32, the select gate electrode 12 and the select gate dielectric film 6 are formed by photolithography and dry etching.

Subsequently, as shown in FIG. 33, the ONO film 18 composed of the three layers of SiO₂ film/SiN film/SiO₂ film, which stores the charge is deposited, and a conductive film 20 made of amorphous silicon is deposited as the gate electrode material of the memory transistor. Since the conductive film 20 made of amorphous silicon is uniformly formed, the upper surface of the conductive film 20 reflects the roughness of an underlying conductive film made of polysilicon, that is, the roughness of the select gate electrode 12.

Subsequently, as shown in FIG. 34, the conductive film 20 is etched-back by anisotropic dry etching, so that only the sidewall gate electrodes to be the memory gate electrodes 11 are left, and the exposed ONO film 18 is removed by wet etching.

At this stage, as shown in FIG. 35, in reflection of the surface roughness of the upper surface of the select gate electrode 12, the gate length Lmg of the memory gate electrode 11, which is the sidewall electrode, fluctuates (Lmg 1<Lmg 2).

An ideal sidewall electrode is not affected by the height of the select gate electrode of the sidewall on which it is formed. However, (1) in the case where the height of the select gate electrode is not sufficiently large in comparison with a deposition thickness of the film to be the sidewall electrode, and (2) in the case where the sidewall of the select gate electrode is tapered, the gate length (sidewall length) of the memory transistor also increases in proportion to the height of the memory gate electrode.

The height of the gate electrode tends to decrease in an advanced process in which feature size is more scaled down. However, the gate length of the memory transistor and the ONO film thickness are not scaled to the same extent as the advanced process because of the requirement of reliability as a nonvolatile memory, and a ratio of the height of the select gate electrode to the memory gate electrode is deviated from the ideal one and comes close to the condition (1). Further, since the electric field of a corner portion is alleviated and reliability can be enhanced by tapering the sidewall of the select gate electrode, the condition (2) is positively introduced in some cases. As described above, in the actual device, the inventors of the present invention have found that even a sidewall structure has a problem that the gate length of the memory transistor fluctuates depending on the height of the select gate electrode made of polysilicon.

An object of the present invention is to provide a technology for suppressing the variation in the gate length of the memory transistor formed to have the sidewall structure.

The above and other objects and novel characteristics of the present invention will be apparent from the description of this specification and the accompanying drawings.

The typical ones of the inventions disclosed in this application will be briefly described as follows.

In a fabricating method of the nonvolatile semiconductor memory device of the present invention, after a gate dielectric film of the select transistor and a select gate electrode material made of polysilicon are deposited on a semiconductor substrate, the select gate electrode material is planarized by polishing and then patterned, thereby forming a select gate electrode. Subsequently, after depositing a gate dielectric film of the memory transistor and a memory gate electrode material made of amorphous silicon on the planarized select gate electrode and the semiconductor substrate, the memory gate electrode material is etched-back, thereby forming a self align memory gate electrode.

The effects obtained by typical aspects of the present invention will be briefly described below.

By planarizing the surface of the select gate electrode made of polysilicon, the variation in the gate length of the memory transistor formed to have the sidewall structure can be suppressed.

### BRIEF DESCRIPTIONS OF THE DRAWINGS

FIG. 1 is a fabrication flowchart of a memory cell shown in a first embodiment of the present invention;

FIG. 2 is an explanatory drawing schematically showing the memory cell in the fabricating process shown in the first embodiment;

FIG. 3 is an explanatory drawing schematically showing the memory cell in the fabricating process subsequent to FIG. 2;

FIG. 4 is an explanatory drawing schematically showing the memory cell in the fabricating process subsequent to FIG. 3;

FIG. 5 is an explanatory drawing schematically showing the memory cell in the fabricating process subsequent to FIG. 4;

FIG. 6 is an explanatory drawing schematically showing the memory cell in the fabricating process subsequent to FIG. 5;

FIG. 7 is a fabrication flowchart of the memory cell shown in a second embodiment of the present invention;

FIG. 8 is an explanatory drawing schematically showing the memory cell in the fabricating process shown in the second embodiment;

FIG. 9 is an explanatory drawing schematically showing the memory cell in the fabricating process subsequent to FIG. 8;

FIG. 10 is an explanatory drawing schematically showing the memory cell in the fabricating process subsequent to FIG. 9;

FIG. 11 is an explanatory drawing schematically showing the memory cell in the fabricating process subsequent to FIG. 10;

FIG. 12 is an explanatory drawing schematically showing the memory cell in the fabricating process subsequent to FIG. 11;

FIG. 13 is an explanatory drawing schematically showing the memory cell in the fabricating process subsequent to FIG. 12;

FIG. 14 is a fabrication flowchart of the memory cell shown in a third embodiment of the present invention;

FIG. 15 is an explanatory drawing schematically showing the memory cell in the fabricating process shown in the third embodiment;

FIG. 16 is an explanatory drawing schematically showing the memory cell in the fabricating process subsequent to FIG. 15;

FIG. 17 is a cross-sectional view schematically showing the memory cell studied by the inventors of the present invention;

FIG. 18 is an explanatory drawing of an array structure using the memory cell of FIG. 17;

FIG. 19 is an explanatory drawing of a plane layout of the array structure of FIG. 18;

FIG. 20 is an explanatory drawing of the voltage conditions at the time of operating the memory cell of FIG. 17;

FIG. 21 is an explanatory drawing schematically showing the memory cell and a logic circuit transistor in the fabricating process of a nonvolatile semiconductor memory device studied by the inventors of the present invention;

FIG. 22 is an explanatory drawing schematically showing the memory cell and the logic circuit transistor in the fabricating process subsequent to FIG. 21;

FIG. 23 is an explanatory drawing schematically showing the memory cell and the logic circuit transistor in the fabricating process subsequent to FIG. 22;

FIG. 24 is an explanatory drawing schematically showing the memory cell and the logic circuit transistor in the fabricating process subsequent to FIG. 23;

FIG. 25 is an explanatory drawing schematically showing the memory cell and the logic circuit transistor in the fabricating process subsequent to FIG. 24;

FIG. 26 is an explanatory drawing schematically showing the memory cell and the logic circuit transistor in the fabricating process subsequent to FIG. 25;

FIG. 27 is an explanatory drawing schematically showing the memory cell and the logic circuit transistor in the fabricating process subsequent to FIG. 26;

FIG. 28 is an explanatory drawing schematically showing the memory cell and the logic circuit transistor in the fabricating process subsequent to FIG. 27;

FIG. 29 is an explanatory drawing of the relationship between a gate length of a memory transistor and IV characteristics;

FIG. 30 is an explanatory drawing of the relationship between a gate length of a memory transistor and memory erasing speed;

FIG. 31 is an explanatory drawing schematically showing the memory cell in the fabricating process of the nonvolatile semiconductor memory device studied by the inventors of the present invention;

FIG. 32 is an explanatory drawing schematically showing the memory cell in the fabricating process subsequent to FIG. 31;

FIG. 33 is an explanatory drawing schematically showing the memory cell in the fabricating process subsequent to FIG. 32;

FIG. 34 is an explanatory drawing schematically showing the memory cell in the fabricating process subsequent to FIG. 33; and

FIG. 35 is an explanatory drawing schematically showing the memory cell of FIG. 34.

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

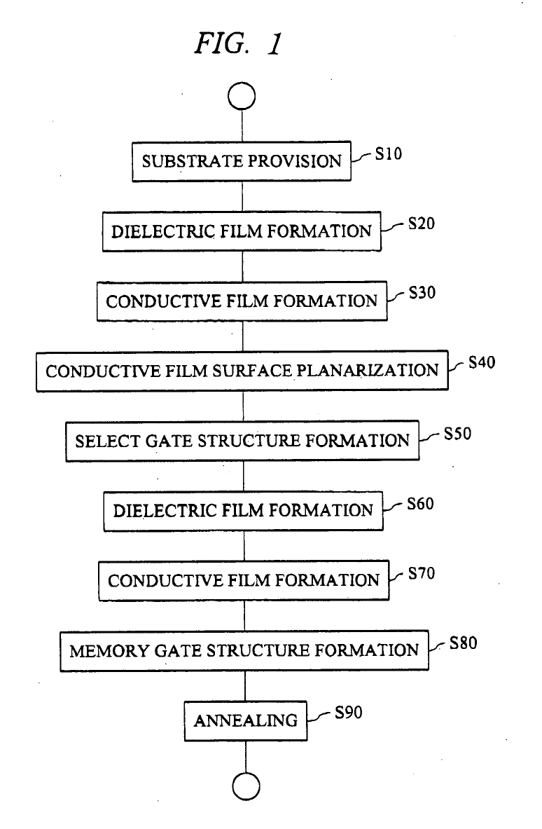

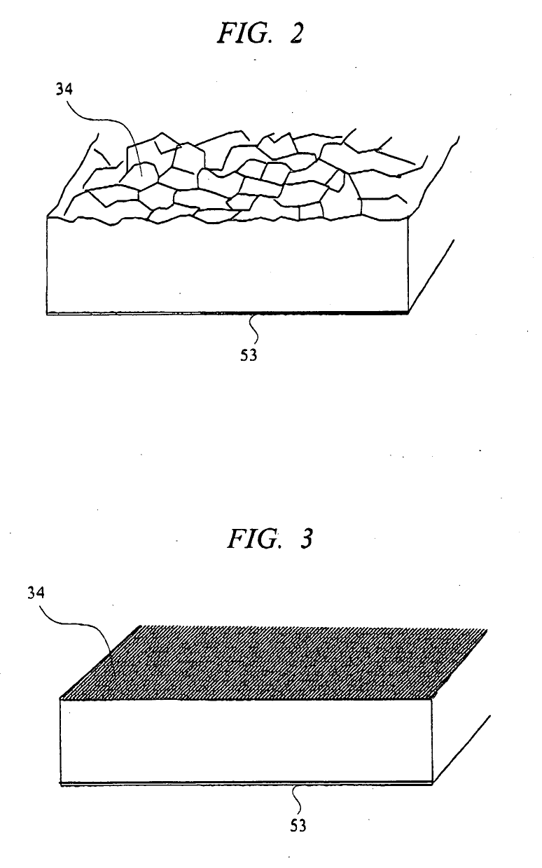

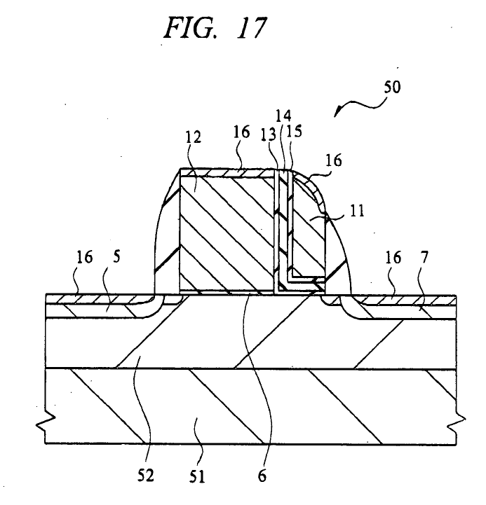

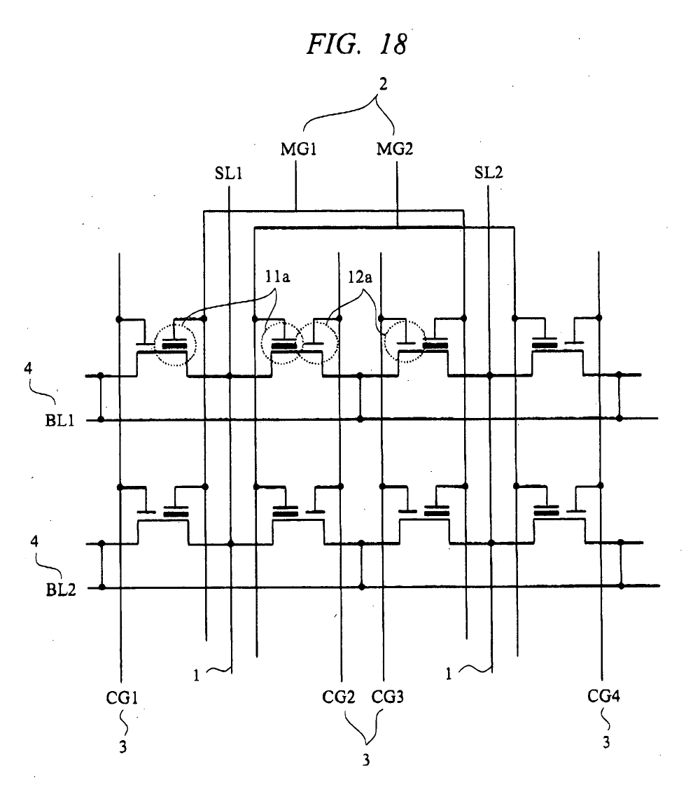

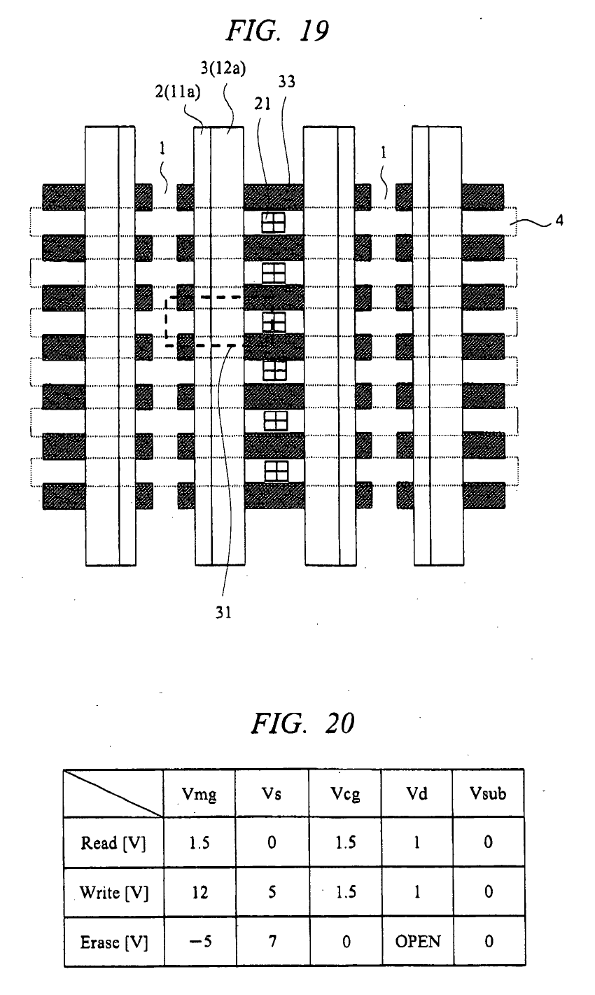

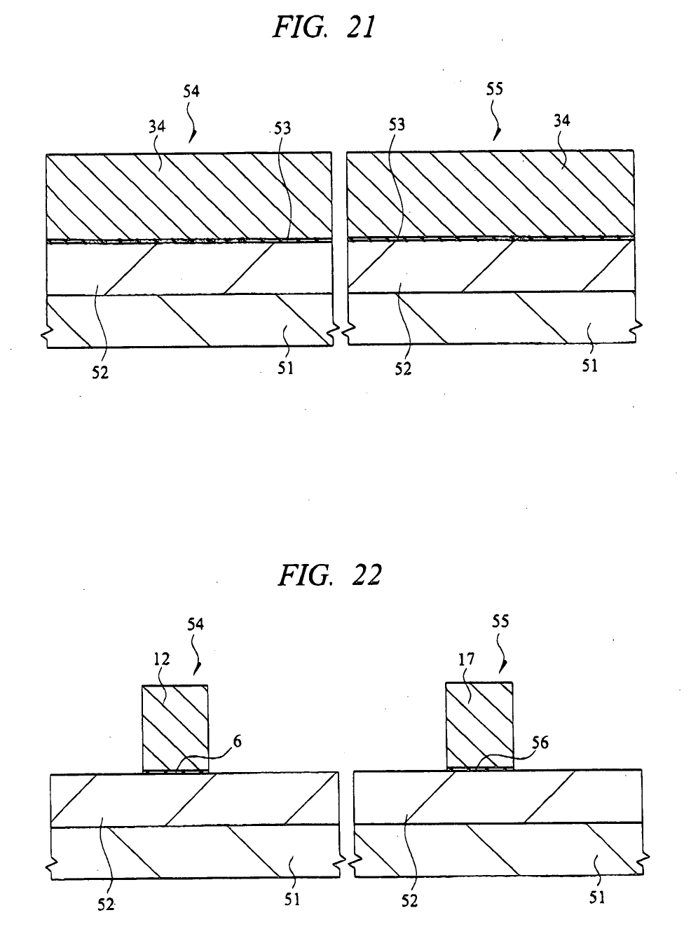

A fabricating method of a memory cell shown in a first embodiment of the present invention will be described with reference to FIG. 1 to FIG. 6. FIG. 1 is a fabrication flowchart of the memory cell shown in the first embodiment of the present invention, and FIG. 2 to FIG. 6 are explanatory drawings schematically showing the memory cell in the fabricating process. Note that the memory cell is a split gate MONOS memory cell shown in FIG. 17, an array structure is as shown in FIG. 18, and a cell layout is as shown in FIG. 19. A portion surrounded by dotted line 31 in FIG. 19 corresponds to unit memory cell. In adjacent cells, arrangement of a select gate and a memory gate is always symmetrical. Also, the voltage conditions of FIG. 20 are applied to the reading, programming, and erasing operations. Furthermore, a basic fabrication flow confirms to the method described in the “summary of the invention”. A process rule of 150 nm node is used for fabrication.

First, for example, a semiconductor substrate (semiconductor wafer processed into a circular thin plate) made of a p type single crystal silicon is prepared (step S10). In this semiconductor substrate, isolation area and well are formed through a known process.

Next, as shown in FIG. 2, a dielectric film 53 with a thickness of 4 nm is deposited at 800° C. as a gate dielectric film of the select transistor on the semiconductor substrate (not shown), and subsequently, a conductive film 34 made of polysilicon is deposited to have a thickness of 270 nm (steps S20 and S30). The deposition of the conductive film 34 made of polysilicon is performed under the conditions for minimizing the crystal grain size, that is, at the deposition temperature of 640° C. without dopant doping. Even in this case, the surface roughness of about 10 nm is formed due to the growth of polysilicon crystal grains.

Next, as shown in FIG. 3, the surface of the conductive film 34 is planarized by a CMP (Chemical Mechanical Polishing) method in order to remove the surface roughness of the conductive film 34 (step S40). The CMP method mentioned here is a generally used method in the process of forming shallow trench isolation and the planarizing process of an interlayer dielectric, in which the surface of SiO₂ film or the like is polished and planarized by using slurry in which polishing agent is dispersed and a polishing pad made by polyurethane or the like. Depending on the combination of slurry and the polishing pad, various materials other then SiO₂ film can be processed such as a tungsten film, a Cu film, and a polysilicon film.

In the present embodiment, with respect to the change in the surface roughness before and after the surface polishing of the conductive film 34 made of polysilicon by the CMP method, the surface roughness is 8 angstroms after polishing in terms of rms values whereas it is 60 angstroms before polishing, and this is a reduction of about one digit. The polishing is performed under the conditions that silica slurry is used for the polyurethane pad, polishing pressure is 150 g/cm², and the number of rotations is 20 rpm. This purpose can be achieved even when the polishing amount of CMP is smaller in comparison with that of the ordinary polishing of the interlayer dielectric film, and 20 nm is polished in the flat region. Since the polishing amount is small, the variation in CMP polishing does not cause any problem. Note that, in the present embodiment, the CMP method is used for planarizing the surface of the conductive film 34, but various types of planarizing methods such as the etchback, SOG method and the like may be also applied. However, since the CMP method is the highest in planarizing capability from among various types of planarizing methods such as the etchback, the SOG method and the like, the variation in the gate length of the memory gate to be formed later can be further reduced by applying the CMP method.

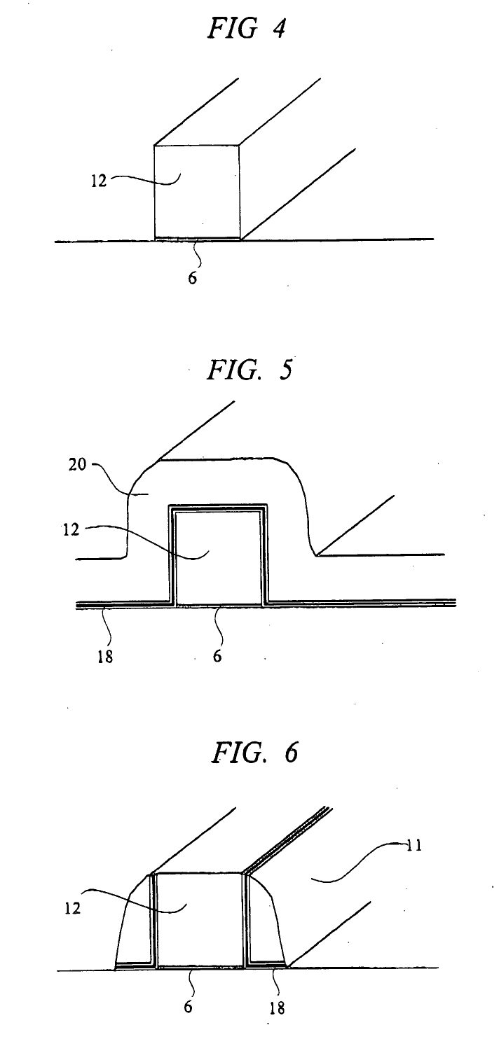

Next, as shown in FIG. 4, the select gate is formed by photolithography and dry etching (step S50). That is, the conductive film 34 and the dielectric film 53 are patterned, thereby forming the select gate electrode 12 and the select gate dielectric film 6.

Next, as shown in FIG. 5, the ONO film 18 composed of three layers of SiO₂ film/SiN film/SiO₂ film is formed as a charge storage film (dielectric film), and a conductive film 20 made of amorphous silicon doped with a dopant to be a memory gate electrode is formed (steps S60 and S70). Since the amorphous silicon film does not contain crystal grains, the amorphous silicon film has an advantage that it is uniformly formed without surface roughness.

Next, as shown in FIG. 6, the conductive film 20 made of an amorphous silicon film is etched back by anisotropic dry etching, and the unnecessary ONO film 18 is removed by dry etching and wet etching, while leaving only the sidewall gate electrode to be the memory gate electrode 11 (step S80).

After the conductive film 34 made of polysilicon of the select gate electrode material is deposited, the CMP method is used to remove the surface roughness of about 10 nm. Therefore, if the sidewall gate electrode in succession to the select gate electrode 12 is formed based on the planarized surface after the CMP, the variation in the gate length of the sidewall gate can be suppressed. More specifically, as a result of the reduction of the upper surface roughness of the select gate electrode 12 by one digit by the CMP, the variation in the gate length of the memory gate electrode 11 which is the sidewall electrode formed based on the select gate electrode 12 can be reduced by nearly one digit from ±10 nm to ± several nm.

Next, in order to form the oxide film for the memory gate protection and crystallize the amorphous silicon, the annealing is performed in oxidizing atmosphere at 800° C. (step S90).

The split gate MONOS memory cell shown in the present embodiment which is formed through the above-described fabricating process can suppress the variation in the gate length of the sidewall structure thereof from ±10 nm to ± several nm by nearly one digit.

The characteristics of the memory transistor can be enhanced by suppressing the variation in the gate length of this memory transistor. This is because the gate length of the memory transistor is the dominating factor of the short channel characteristic and affects leakage current values and the threshold voltage, and the gate length of the memory transistor affects also the erasing speed of the nonvolatile memory. Consequently, by suppressing the variation in the gate length in the memory array, the variation in leakage current values, threshold voltage and erasing speed can be suppressed. Further, when the leakage current variation is suppressed, the current consumption is reduced, and when the threshold voltage variation is suppressed, the programming conditions for ensuring the characteristics of worst bits can be alleviated and the programming durability can be enhanced. Further, since the suppression of the erasing speed variation corresponds to the substantial alleviation of erasing conditions determined by the characteristics of the worst bits, programming/erasing endurance can be enhanced.

### Second Embodiment

In a second embodiment, the case where, after the conductive film of the gate electrode material made of polysilicon is formed in the fabricating process of the memory cell shown in the first embodiment, a cap layer made of SiO₂ is formed thereon, and the cap layer made of SiO₂ is planarized by CMP method will be described.

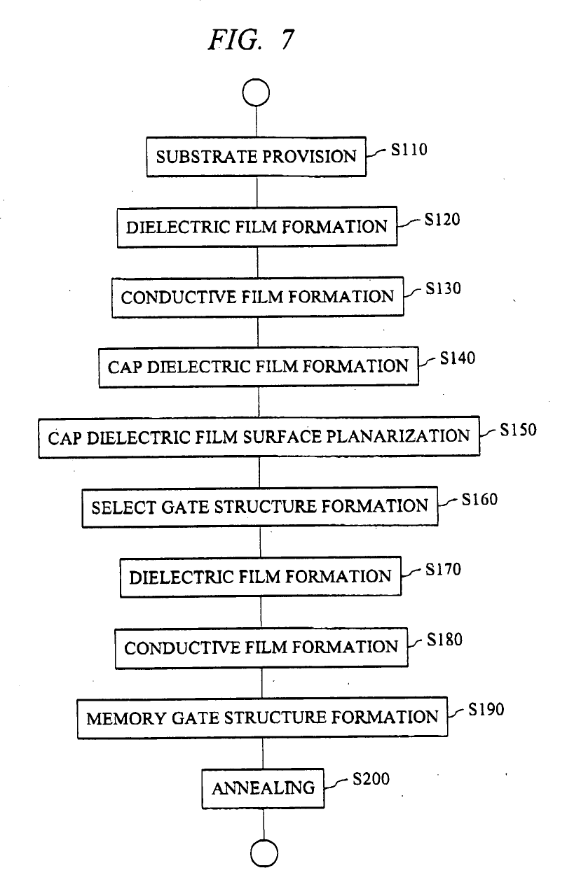

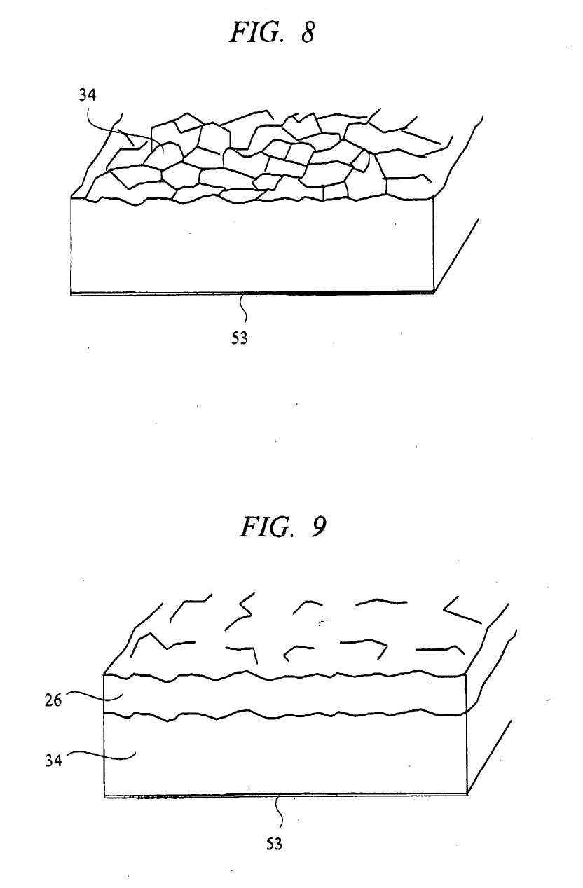

The fabricating method of a memory cell shown in the second embodiment of the present invention will be described with reference to FIG. 7 to FIG. 13. FIG. 7 is a fabrication flowchart of the memory cell shown in the second embodiment of the present invention, and FIG. 8 to FIG. 13 are explanatory drawings schematically showing the memory cell in the fabricating process. Note that the basic structure, layout, process rule and the like of the memory cell are the same as those of the first embodiment.

First, after a semiconductor substrate is prepared, a dielectric film and a conductive film are formed on the semiconductor substrate (not shown) as shown in FIG. 8 (steps S110 to S130). More specifically, a thermal oxide film with a thickness of 3 nm is formed as a dielectric film 53 to be the gate dielectric film of a select transistor at 800° C. on the semiconductor substrate made of silicon, and subsequently, a conductive film 34 to be a gate electrode is deposited to have a thickness of about 250 nm. Note that, in this semiconductor substrate, an isolation area and a well are formed through a known process.

Subsequently, as shown in FIG. 9, a cap layer 26 made of a silicon oxide film is deposited to have a thickness of about 70 nm by a CVD method (step S140). The deposition of the polysilicon is performed under the conditions for minimizing the crystal grain size, that is, at the deposition temperature of 640° C. without dopant doping. Even in this case, however, the surface roughness of about 10 nm is formed due to the growth of polysilicon crystal grains. Therefore, a surface roughness is formed also on the surface of the cap layer 26 made of a SiO₂ film deposited on the rough surface.

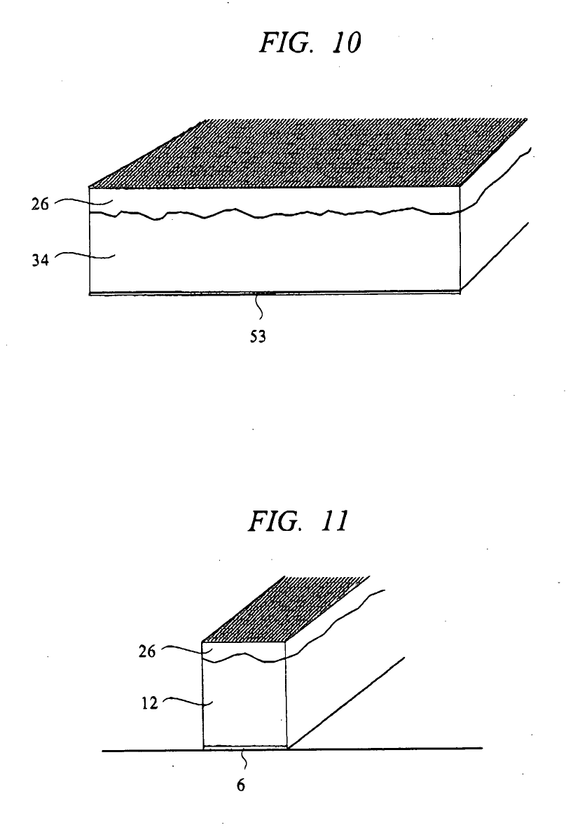

Subsequently, as shown in FIG. 10, the surface of the cap film 26 made of a SiO₂ film is planarized by the CMP method in order to remove the surface roughness of the cap film 26 (step S150). The polishing is performed under the conditions that silica slurry is used for the polyurethane pad, polishing pressure is 200 g/cm², and the number of rotations is 20 rpm. This purpose can be achieved even when the polishing amount of CMP is smaller in comparison with that of the ordinary polishing of the interlayer dielectric film, and 20 nm is polished in the flat region. Since the polishing amount is small, the variation in CMP polishing does not cause any problem.

Subsequently, as shown in FIG. 11, the select gate is formed by photolithography and dry etching (step S160). That is, the cap layer 26, the conductive film 34 and the dielectric film 53 are patterned, thereby forming the select gate electrode 12 and the select gate dielectric film 6.

Subsequently, as shown in FIG. 12, the ONO film 18 composed of three layers of SiO₂ film/SiN film/SiO₂ film is formed as a charge storage film (dielectric film), and a conductive film 20 made of amorphous silicon doped with a dopant to be a memory gate electrode is formed (steps S170 and S180). Since the amorphous silicon film does not contain crystal grains, the amorphous silicon film has an advantage that it is uniformly formed without surface roughness.

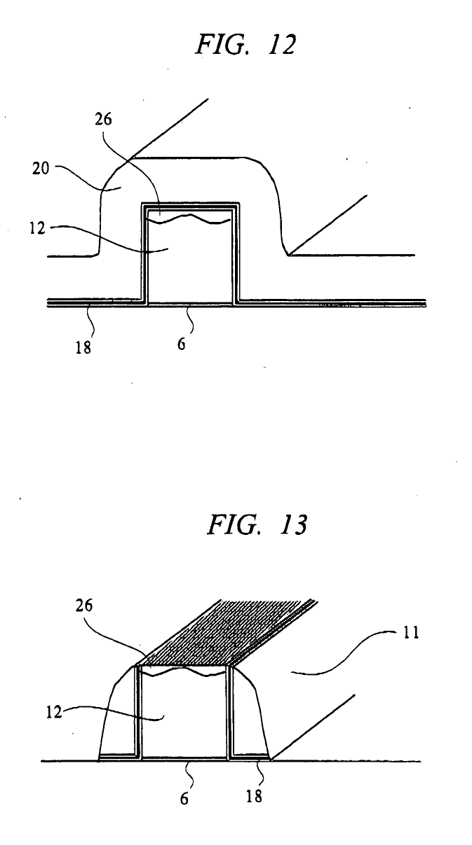

Subsequently, as shown in FIG. 13, the conductive film 20 made of an amorphous silicon film is etched back by anisotropic dry etching, and the unnecessary ONO film 18 is removed by dry etching and wet etching, while leaving only the sidewall gate electrode to be the memory gate electrode 11 (step S190). Incidentally, by the cleaning at each step in the processes so far, the cap layer 26 made of a SiO₂ film is etched and reduced, and at the step of FIG. 13, the layer 26 is slightly left or the polysilicon surface of the select gate electrode is exposed. However, in terms of the uniform formation of the gate length, there is no inconvenience because the purpose can be achieved when the surface is flat at the step of FIG. 12 where the memory gate electrode is deposited.

After the cap layer 26 made of a SiO₂ film is deposited on the conductive film 34 to be the select gate electrode 12, the CMP method is used to remove the surface roughness of about 10 nm. Therefore, if the sidewall gate electrode in succession to the select gate electrode 12 is formed based on the planarized surface after the CMP, the variation in the gate length of the sidewall gate can be suppressed. More specifically, as a result of the reduction of the upper surface roughness of the select gate electrode 12 by one digit by the CMP, the variation in the gate length of the memory gate electrode 11 which is the sidewall electrode formed based on the select gate electrode 12 can be reduced by nearly one digit from ±10 nm to ± several nm.

Subsequently, in order to form the oxide film for the memory gate protection and crystallize the amorphous silicon, the annealing is performed in oxidizing atmosphere at 800° C. (step S200).

The split gate type MONOS memory cell shown in the present embodiment which is formed through the above-described fabricating process can suppress the variation in the gate length of the sidewall structure thereof from ±10 nm to ± several nm by nearly one digit.

Different from the first embodiment, the cap layer 26 made of a SiO₂ film is deposited on the conductive film 34 made of polysilicon and this cap layer 26 is planarized in the present embodiment. More specifically, in the present embodiment, an object to be polished by the CMP method is the dielectric film made of SiO₂. Note that, since the CMP of SiO₂ is widely used for the shallow trench isolation process and the planarizing of an interlayer dielectric, when SiO₂ is taken as the object to be polished instead of polysilicon, the polishing equipment, polishing material, and cleaning method after polishing can be used in common. Even when the object to be polished by the CMP is either of polysilicon or SiO₂, the variation in the gate length of the memory gate can be suppressed. Therefore, it is only necessary to make an appropriate choice in accordance with the structure of the fabrication line and the fabricating process.

### Third Embodiment

In a third embodiment, the case where the gate length of the select transistor is set to 120 nm or more in the fabricating process of the memory cell shown in the first embodiment will be described.

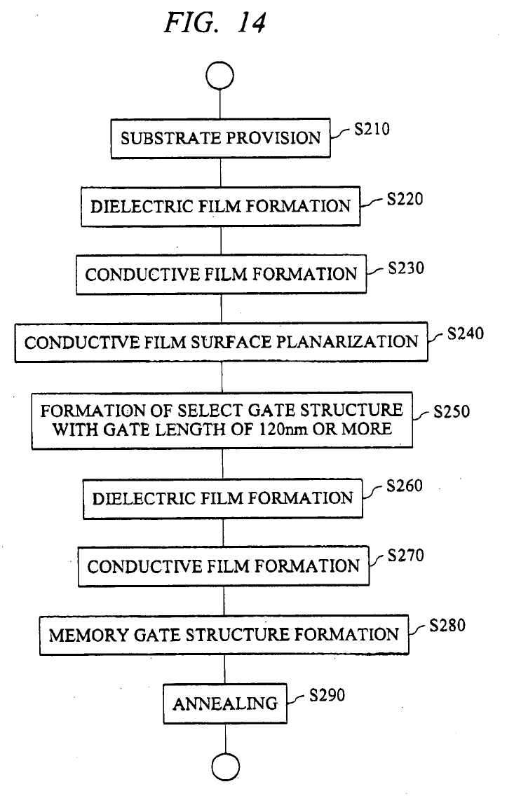

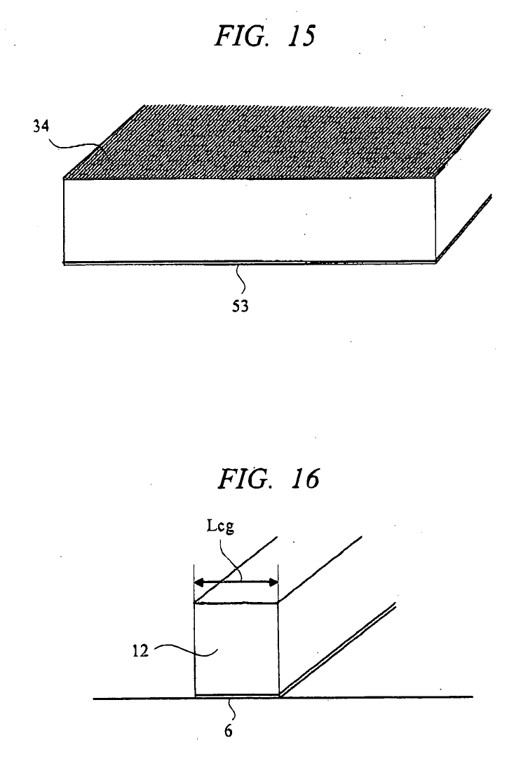

The fabricating method of the memory cell shown in the third embodiment will be described with reference to FIG. 14 to FIG. 16. FIG. 14 is a fabrication flowchart of the memory cell shown in the third embodiment of the present invention, and FIG. 15 and FIG. 16 are explanatory drawings schematically showing the memory cell in the fabricating process. Note that the basic structure, layout, process rule and the like of the memory cell are the same as those of the first embodiment.

First, after a semiconductor substrate is prepared, a dielectric film and a conductive film are formed on the semiconductor substrate (steps S210 to S230). More specifically, a thermal oxide film with a thickness of 3 nm is formed as a dielectric film to be the gate dielectric film of a select transistor at 800° C. on the semiconductor substrate made of silicon, and subsequently, a conductive film to be a gate electrode is deposited to have a thickness of about 250 nm. Note that, in this semiconductor substrate, an isolation area and a well are formed through a known process.

Subsequently, as shown in FIG. 15, the surface of the conductive film 34 is planarized by the CMP method in order to remove the surface roughness of the conductive film 34 (step S240).

Subsequently, as shown in FIG. 16, the select gate is formed by photolithography and dry etching (step S250). That is, the conductive film 34 and the dielectric film 53 are patterned, thereby forming the select gate electrode 12 and the select gate dielectric film 6. At this time, the gate length Lcg of the select gate electrode 12 is 120 nm or more and has a size large enough to be patterned by lithography equipment, which can use a sufficiently thick photoresist with using a general KrF excimer laser, i-lay, or a part of ArF exciter laser as a light source.

The methods of planarizing the upper surface of the gate electrode having polysilicon deposited thereon by CMP are disclosed in Patent Document 4 and others. However, these methods are the technologies effective in the case where a depth of focus margin and a photoresist height variation margin are reduced and the planarization of the surface roughness of the upper surface of polysilicon is required for appropriate pattern exposure, when a lithography technology in which the ArF excimer laser is used as a light source and a thin photoresist of 200 nm or less is required so as to form further scaled pattern is used. Thus, in the photolithography in which a KrF light source capable of ensuring a sufficient margin is used and a sufficiently thick photoresist is used, such techniques are not required to be added in general.

However, in the present embodiment, similar to the first embodiment, an ONO film composed of three layers of SiO₂ film/SiN film/SiO₂ film to be a charge storage film (dielectric film) is deposited, and a conductive film to be a memory gate electrode is deposited. Thereafter, the conductive film is etched-back by anisotropic dry etching, thereby forming the memory gate electrode in the shape of a sidewall. More specifically, since the gate length of the memory gate electrode varies by reflecting the variation in height of the upper surface of the select gate electrode to be the basis thereof as described above, a step of planarizing the surface roughness of the polysilicon film to be the select gate by the CMP method is added in order to suppress the variation. In this manner, the memory gate electrode formed as a sidewall has the uniform gate length.

As described above, in the memory using the sidewall gate, even in a device relatively large in size using the KrF lithography equipment, which does not require the ArF lithography equipment and a thin film photoresist, an effect of suppressing the variation can be obtained by planarizing the upper surface of the select gate electrode in relation to using the sidewall for an electrode. Further, as another important effect, under the condition that the gate length of the select gate electrode is 120 nm or more, dry etching resistance at the gate patterning process can be increased since a sufficiently thick photoresist can be used, and the polysilicon height of the gate electrode of 250 nm or more can be sufficiently guaranteed. If the height of polysilicon is 250 nm or more, in the ion implantation for forming high concentration doped regions of source and drain with using the gate electrode including the sidewall electrode lower than the gate electrode polysilicon as a mask, it is possible to prevent an ion penetration through the gate electrode to be implanted into a channel region. This is an important characteristic in the device using the sidewall gate structure, which is in principle inevitably formed lower in height than the other gate.

Subsequently, in order to form the oxide film for the memory gate protection and crystallize the amorphous silicon, the annealing is performed in oxidizing atmosphere at 800° C. (step S290).

The split gate MONOS memory cell shown in the present embodiment which is formed through the above-described fabricating process can suppress the variation in the gate length of the sidewall structure thereof from ±10 nm to ± several nm by nearly one digit.

In the foregoing, the invention made by the inventors of the present invention has been concretely described based on the embodiments. However, it is needless to say that the present invention is not limited to the foregoing embodiments and various modifications and alterations can be made within the scope of the present invention.

In the above-described embodiments, the case where the conductive film made of polysilicon is applied as the gate electrode material of the select transistor has been described. However, it is also possible to apply a conductive film made of amorphous silicon.

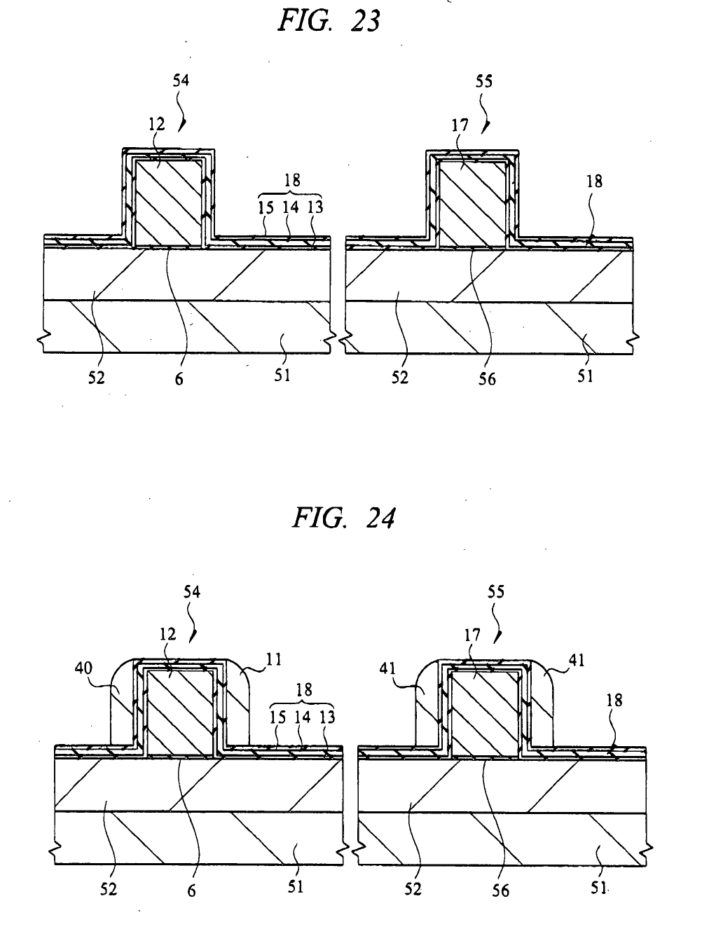

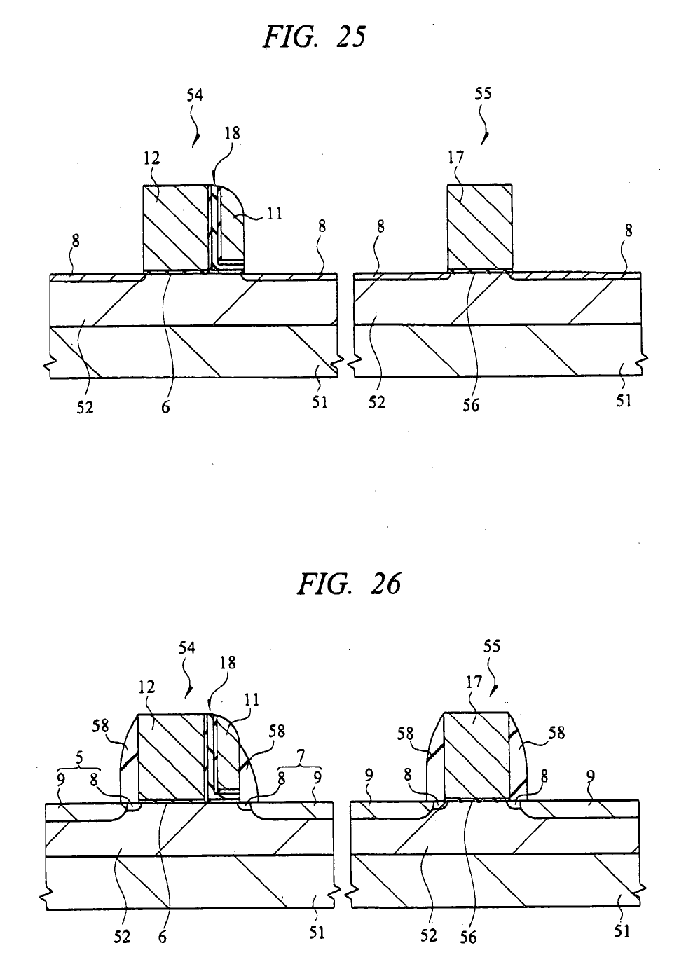

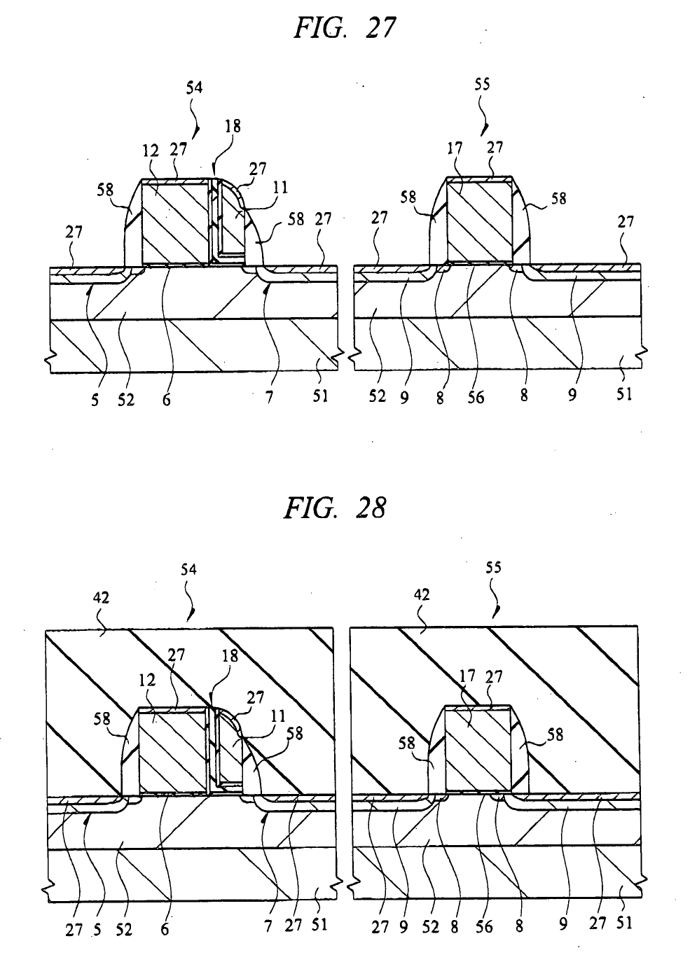

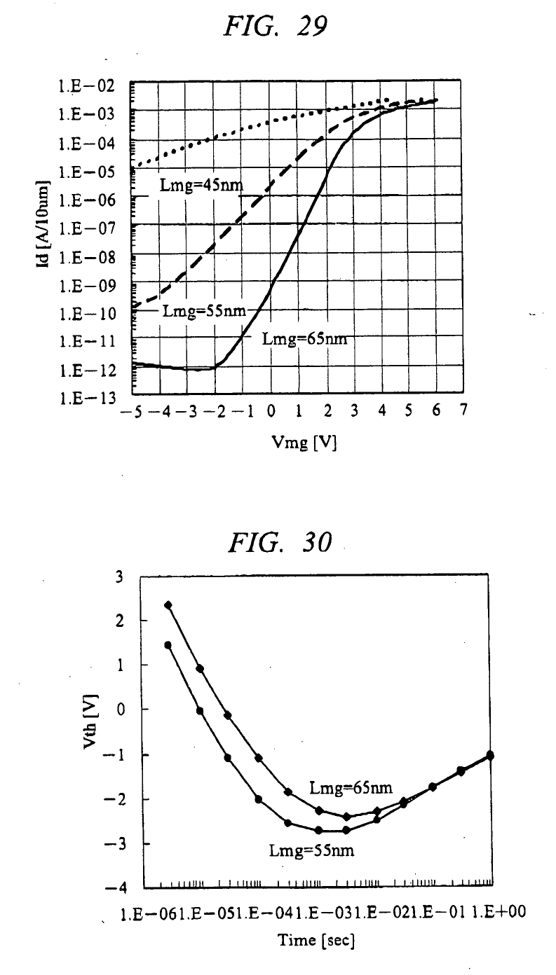

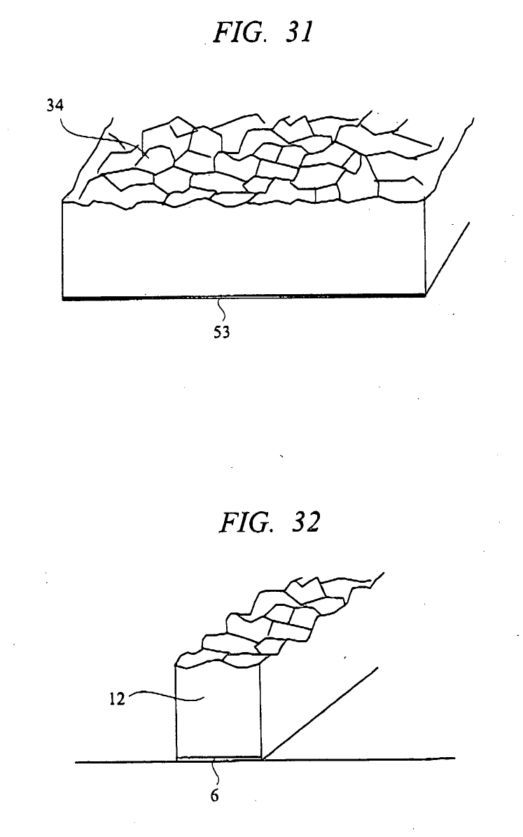

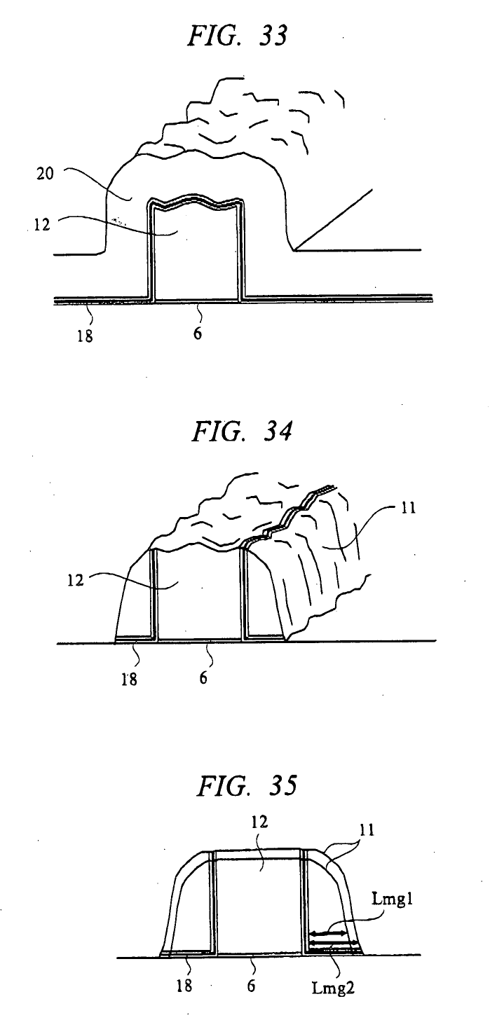

Further, in the first to third embodiments, the memory cell having the structure in which the select gate electrode is formed first and the memory gate electrode is then formed as the sidewall has been described. However, it is also possible to adopt the structure in which the order of formation of both electrodes is reversed. When this structure is adopted, the variation in size of the gate electrode formed as the sidewall of the self align split gate structure can be suppressed without any distinction between the memory gate and the select gate. From this viewpoint, contrary to the first to third embodiments, a process can be changed to such an order that the memory gate electrode is fabricated first with using a mask, and the select electrode is then formed as the sidewall for this electrode. Specifically, the first dielectric film 6 of FIG. 22 is replaced and formed as a first gate dielectric film including the trap film, thereby forming the first gate electrode 12. Thereafter, the surface roughness of the first gate electrode is planarized by polishing, and subsequently, the second gate dielectric film 18 shown in FIG. 23 is replaced and formed as a silicon oxide film, thereby forming the second gate electrode 11 shown in FIG. 24 as a sidewall. The completed cross section is equivalent to FIG. 17 where the first gate dielectric film 6 is replaced as a film including the trap film and the second dielectric films 13, 14, and 15 are replaced as the single silicon oxide film. Consequently, a reference numeral 12 of FIG. 17 corresponds to the memory gate electrode, and a reference numeral 11 corresponds to the select gate electrode. In the structure obtained by this change of the process, since the variation in the characteristic of the select gate electrode can be suppressed, an effect of suppressing the variation in current at the time of reading operations and the variation in programming speed at the time of programming operations can be obtained.

The present invention can be widely used in manufacturing industries for fabricating the semiconductor devices.

What is claimed is:

1. A fabricating method of a nonvolatile semiconductor memory device, comprising:
a first dielectric film formed on a main surface of a semiconductor substrate;
a first gate electrode made of a first conductive film formed on said first dielectric film;
a second dielectric film formed on a sidewall of said first gate electrode and said main surface;
a second gate electrode made of a second conductive film formed on said second dielectric film; and
doped regions to be source and drain formed in said semiconductor substrate below said first gate electrode and said second gate electrode,
said fabricating method comprising the steps of:
(a) forming said first dielectric film on said main surface and then forming said first conductive film on said first dielectric film;
(b) planarizing a surface of said first conductive film by a CMP method;
(c) forming said first gate electrode by patterning said first conductive film;
(d) forming said second dielectric film on the sidewall of said first gate electrode and said main surface and forming said second conductive film on said second dielectric film; and
(e) etching back said second conductive film to form said second gate electrode.

2. The fabricating method of a nonvolatile semiconductor memory device according to claim 1,
wherein, in said step (d), said second conductive film is formed of amorphous silicon.

3. The fabricating method of a nonvolatile semiconductor memory device according to claim 1,
wherein, in said step (d), said second conductive film is formed of amorphous silicon doped with a dopant.

4. The fabricating method of a nonvolatile semiconductor memory device according to claim 1,
wherein, in said step (a), said first conductive film is formed of polysilicon not doped with any dopant.

5. The fabricating method of a nonvolatile semiconductor memory device according to claim 1,
wherein said second dielectric film is composed of a first oxide film, a trap dielectric film, and a second oxide film formed on the sidewall of said first gate electrode and said main surface, and
said step (d) includes the steps of:
(d1) forming said first oxide film on the sidewall of said first gate electrode and said main surface;
(d2) forming said trap dielectric film on said first oxide film; and
(d3) forming said second oxide film on said trap dielectric film.

6. The fabricating method of a nonvolatile semiconductor memory device according to claim 1,
wherein, in said step (c), said first gate electrode is formed so that a gate length of said first gate electrode is set to 120 nm or more.

7. The fabricating method of a nonvolatile semiconductor memory device according to claim 1,
wherein, in said step (c), patterning is performed by a photolithography method using KrF light source.

8. The fabricating method of a nonvolatile semiconductor memory device according to claim 1, further comprising the step of; (f) forming said doped regions by an ion implantation method with using said second gate electrode as a mask.

9. A fabricating method of a nonvolatile semiconductor memory device, comprising:
a first dielectric film formed on a main surface of a semiconductor substrate;
a first gate electrode composed of a first conductive film formed on said first dielectric film;
a cap dielectric film formed on said first gate electrode;
a second dielectric film formed on a sidewall of said first gate electrode and said main surface;
a second gate electrode composed of a second conductive film formed on said second dielectric film; and
doped regions to be source and drain formed in said semiconductor substrate below said first gate electrode and said second gate electrode,
said fabricating method comprising the steps of:
(a) forming said first dielectric film on said main surface and then forming said first conductive film on said first dielectric film;
(b) forming said cap dielectric film on said first conductive film;
(c) planarizing a surface of said cap dielectric film by a CMP method;
(d) forming said first gate electrode by patterning said cap dielectric film and said first conductive film;
(e) forming said second dielectric film on the sidewall of said first gate electrode and said main surface and forming said second conductive film on said second dielectric film; and
(f) etching back said second conductive film to form said second gate electrode.

10. The fabricating method of a nonvolatile semiconductor memory device according to claim 9,
wherein, in said step (e), said second conductive film is formed of amorphous silicon.

11. The fabricating method of a nonvolatile semiconductor memory device according to claim 9,
wherein, in said step (e), said second conductive film is formed of amorphous silicon doped with a dopant.

12. The fabricating method of a nonvolatile semiconductor memory device according to claim 9,
wherein, in said step (a), said first conductive film is formed of polysilicon not doped with any dopant.

13. The fabricating method of a nonvolatile semiconductor memory device according to claim 9,
wherein said second dielectric film is composed of a first oxide film, a trap dielectric film, and a second oxide film formed on the sidewall of said first gate electrode and said main surface, and
said step (e) includes the steps of:
(e1) forming said first oxide film on the sidewall of said first gate electrode and said main surface;
(e2) forming said trap dielectric film on said first oxide film; and
(e3) forming said second oxide film on said trap dielectric film.

14. The fabricating method of a nonvolatile semiconductor memory device according to claim 9,
wherein, in said step (d), said first gate electrode is formed so that a gate length of said first gate electrode is set to 120 nm or more.

15. The fabricating method of a nonvolatile semiconductor memory device according to claim 9,
wherein, in said step (d), patterning is performed by a photolithography method using KrF light source.

16. The fabricating method of a nonvolatile semiconductor memory device according to claim 9,
wherein, in said step (d), said cap dielectric film is formed of silicon oxide.

17. The fabricating method of a nonvolatile semiconductor memory device according to claim 9, further comprising the step of: (g) forming said doped regions by an ion implantation method with using said second gate electrode as a mask.
